(19) United States
(12) Patent Application Publication
(10) Pub. No.: US 2020/0027915 A1
(43) Pub. Date: Jan. 23, 2020

(54) OPTICAL SENSOR DEVICE

(71) Applicant: UNITED MICROELECTRONICS CORP., Hsinchu (TW)

(72) Inventor: Cheng-Yu HSIEH, Hsinchu County (TW)

(21) Appl. No.: 16/105,309

(22) Filed: Aug. 20, 2018

(30) Foreign Application Priority Data
Jul. 17, 2018 (CN) 201810785007.7

(51) Int. Cl. H01L 27/146; H01L 31/0236

(52) U.S. Cl. CPC H01L 27/14649; H01L 31/02366; H01L 27/14627; H01L 27/1463; H01L 27/14685; H01L 27/1462; H01L 27/1464; H01L 27/14612; H01L 27/14629

(57) ABSTRACT

An optical sensor device is provided. The optical sensor device includes a semiconductor substrate, a trench isolation element, and a photodiode. The semiconductor substrate has a back semiconductor surface and a front semiconductor surface opposing to the back semiconductor surface. The back semiconductor surface has a textured surface. The trench isolation element is extended from the back semiconductor surface to the front semiconductor surface. The photodiode is in the semiconductor substrate.

This application claims the benefit of People's Republic of China application Serial No. 201810785007.7, filed Jul. 17, 2018, the subject matter of which is incorporated herein by reference.

### BACKGROUND

### Technical Field

The disclosure relates to an optical sensor device, and particularly relates to a backside illuminated image sensor.

### Description of the Related Art

As computer and communications Industries are developed, demands for optical sensor devices such as image sensors with high efficiency are increased, which can be applied in various technical fields such as a digital Camera, a video camera a personal communication system, a game component, a monitor, a micro-camera for medical use, a robot, and so on.

A backside illuminated image sensor is one familiar kind of image sensor devices and has high efficiency. In addition, the backside illuminated image sensor may be fabricated with a process which may be integrated in a conventional semiconductor manufacturing process. Therefore, the backside illuminated image sensor has advantages of low manufacturing cost, small feature size, and high integration. Moreover, the backside illuminated image sensor also has advantages of low operating voltage, low power consumption, high quantum efficiency, low read-out noise, being able to perform random access with need. Thus the backside illuminated image sensor has been widely used in current electronic products.

With trends of component size scaling down and semiconductor manufacturing development, a size of the backside illuminated image sensor becomes smaller. In addition, the backside illuminated image sensor need to meet the requirement of high photo-electric conversion efficiency, high sensitivity, low noise, etc.

### SUMMARY

The present disclosure relates to an optical sensor device.

According to an embodiment, an optical sensor device is disclosed. The optical sensor device comprises a semiconductor substrate, a trench isolation element, and a photodiode. The semiconductor substrate has a back semiconductor surface and a front semiconductor surface opposing to the back semiconductor surface. The back semiconductor surface has a textured surface. The trench isolation element is extended from the back semiconductor surface to the front semiconductor surface. The photodiode is in the semiconductor substrate.

### BRIEF DESCRIPTION OF THE DRAWINGS

FIG. 1 illustrates a diagrammatic cross-section view of an optical sensor device 102 according to an embodiment.

FIG. 2 illustrates a schematic diagram of the semiconductor substrate 104 as viewed with facing toward the back semiconductor surface 104B according to an embodiment.

FIG. 3 illustrates a diagrammatic cross-section view of an optical sensor device 202 according to another embodiment.

FIG. 4 illustrates a schematic diagram of the semiconductor substrate 204 as viewed with facing toward the back semiconductor surface 204B according to an embodiment.

FIG. 5 illustrates a diagrammatic cross-section view of an optical sensor device 302 according to yet another embodiment.

FIG. 6 illustrates a diagrammatic cross-section view of an optical sensor device 402 according to yet another embodiment.

FIG. 7 illustrates a diagrammatic cross-section view of an optical sensor device 502 according to an embodiment.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

### DETAILED DESCRIPTION

Embodiments are provided hereinafter with reference to the accompanying drawings for describing the related procedures and configurations. It is noted that not all embodiments of the invention are shown. Also, it is noted that there may be other embodiments of the present disclosure which are not specifically illustrated. Modifications and variations can be made without departing from the spirit of the disclosure to meet the requirements of the practical applications. It is also important to point out that the illustrations may not be necessarily be drawn to scale. Thus, the specification and the drawings are to be regard as an illustrative sense rather than a restrictive sense. The identical and/or similar elements of the embodiments are designated with the same and/or similar reference numerals.

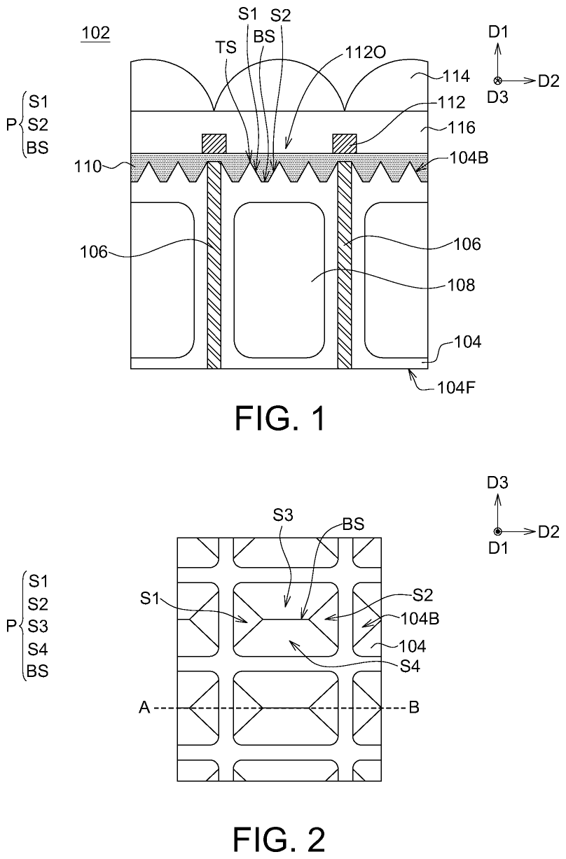

FIG. 1 illustrates a diagrammatic cross-section view of an optical sensor device 102 according to an embodiment. The optical sensor device 102 comprises a semiconductor substrate 104, a trench isolation element 106 and a photodiode 108.

The semiconductor substrate 104 comprises any suitable semiconductor material. In an embodiment, the semiconductor substrate 104 is a silicon substrate, which may consist of silicon. In other embodiments, for example, the semiconductor substrate 104 is a silicon-containing substrate, a III-V group-on-silicon substrate such as a GaN-on-silicon substrate, a graphene-on-silicon substrate, or a silicon-on-insulator (SOI) substrate, and so on, and is not limited thereto. The semiconductor substrate 104 may have photosensitive elements formed therein. In embodiments, the photosensitive element comprises at least a sensing region, such as a photodiode 108. The photosensitive element may also comprise a charge-coupled device, a complementary metal-oxide-semiconductor image sensor (CMOS image sensor, CIS), an active-pixel sensor (API), or a passive-pixel sensor (PPI), and so on.

The semiconductor substrate 104 has a back semiconductor surface 104B and a front semiconductor surface 104F opposing to each other. The back semiconductor surface 104B has a textured surface. In embodiments, the textured surface is a surface having a topology with nanometer to micrometer-sized surface variation in the first direction D1, the second direction D2, and/or the third direction D3 with a textured unit. The textured units may be cones, pyramids, pillars, protrusions, microlenses, sphere-like structures, quantum dots, inverted features, etc., or combinations thereof, but not limited thereto.

FIG. 2 illustrates a schematic diagram of the semiconductor substrate 104 as viewed with facing toward the back semiconductor surface 104B according to an embodiment. A cross-section portion of the semiconductor substrate 104 shown in FIG. 1 may be similar to a cross-section portion taken along AB line in FIG. 2. Referring to FIG. 1 and FIG. 2, in this embodiment, the textured surface is a surface with a variation of a micrometer scale size. For example, the textured surface may comprise textured units P. Each of the textured units P may comprise a first sidewall surface S1, a second sidewall surface S2 and a bottom portion BS between the first sidewall surface S1 and the second sidewall surface S2 opposing to the first sidewall surface S1. The each of the textured units P may further comprise a third sidewall surface S3 and a fourth sidewall surface S4 opposing to the third sidewall surface S3. The third sidewall surface S3 and the fourth sidewall surface S4 are adjoined between the first sidewall surface S1 and the second sidewall surface S2. The bottom portion BS may be a junction between the third sidewall surface S3 and the fourth sidewall surface S4. The first sidewall surface S1, the second sidewall surface S2, the third sidewall surface S3 and the fourth sidewall surface S4 may be inclined surfaces having obtuse angles with the bottom portion BS. In addition, a recess unit is defined by the first sidewall surface S1, the second sidewall surface S2, the third sidewall surface S3, the fourth sidewall surface S4, and the bottom portion BS. The textured surface has a top portion TS between the recess units. The recess unit may have a size of micrometer scale. For example, the largest size of the opening in a second direction D2 may be about 1 μm, but is not limited thereto. The textured surface may be formed by performing a lithographic etching process to the back semiconductor surface 104B. For example, the lithographic etching process may comprise a step performing with using a photo resist and/or hard mask. In the figure, a first direction D1, the second direction D2 and a third direction D3 may intersect each other. For example, the first direction D1 may be a X direction, the second direction D2 may be a Y direction, and the third direction D3 may be a Z direction, substantially perpendicular to each other.

Referring to FIG. 1, the trench isolation element 106 is formed in the semiconductor substrate 104. The trench isolation element 106 may be used to isolate the photosensitive elements from each other. The trench isolation element 106 is extended from the back semiconductor surface 104B to the front semiconductor surface 104F. Opposing surfaces of the trench isolation element 106 are respectively exposed by the back semiconductor surface 1048 and the front semiconductor surface 104F. The trench isolation element 106 may comprise a material having a refractive index different from a refractive index of a material of the semiconductor substrate 104. For example, the material of the trench isolation element 106 may be an insulating material, for example, comprising an oxide such as silicon oxide, but not limited thereto. The trench isolation element 106 may reflect a light into the photosensitive element such as the photodiode 108, and with which photo sensing efficiency can be improved, light interference from an adjacent pixel can be avoided, and sensing accuracy can be increased.

Referring to FIG. 1, the photosensitive element, such as the photodiode 108, may have a thick thickness. For example, the photosensitive element (such as the photodiode 108) may have a thickness (i.e. a size in a first direction D1) being larger than half of the largest thickness of the semiconductor substrate 104, or being larger than ⅔ of the largest thickness of the semiconductor substrate 104, or being larger than ¾ of the largest thickness of the semiconductor substrate 104, or being larger than ⅘ of the largest thickness of the semiconductor substrate 104; and being smaller than the largest thickness of the semiconductor substrate 104. For example, the largest thickness of the semiconductor substrate 104 may be a gap distance between the front semiconductor surface 104F and the most prominent position of the back semiconductor surface 1048 (such as the top portion TS of the textured surface of the back semiconductor surface 104B). The photosensitive element, such as the photodiode 108, may have the thick thickness, for example, from 1 μm to tens of micrometers, with which a path length of a sensing light can be improved.

Referring to FIG. 1, an anti-reflective layer 110 may be disposed on the back semiconductor surface 104B. The anti-reflective layer 110 may be adjoined with the back semiconductor surface 1048, and may have a textured surface complementary to the textured surface of the back semiconductor surface 104B. A grid structure 112 may be disposed on the back semiconductor surface 104B. For example, the grid structure 112 may be disposed on the anti-reflective layer 110. An array of openings 1120 may be defined by the grid structure 112. In an embodiment, the trench isolation element 106 may be corresponded to the grid structure 112, and in other words, the trench isolation element 106 and the grid structure 112 may be overlapped with each other in the third direction D3. The grid structure 112 may comprise a reflective material, such as a metal, or other suitable materials. The grid structure 112 may comprise a conductive material, such as a metal, and may be floating or grounded. The grid structure 112 may be used to reflect a light into the photosensitive element such as the photodiode 108, and with which photo sensing efficiency can be improved, light interference from an adjacent pixel can be avoided, and sensing accuracy can be increased.

A lens 114, such as a micro lens array, may be disposed on the back semiconductor surface 1048. For example, in an embodiment, a transparent layer 116 may be disposed on the anti-reflective layer 110 and the grid structure 112, and the lens 114 may be disposed on the transparent layer 116. In this embodiment, only a portion of the thickness of the transparent layer 116 is occupied by the grid structure 112, and the grid structure 112 is separated from the lens 114 by the transparent layer 116. The transparent layer 116 may comprise an oxide such as silicon oxide, silicon oxynitride, etc., but is not limited thereto. In an embodiment, according to actual demands, a color filter layer may be disposed, for example, between the lens 114 and the transparent layer 116, but is not limited thereto. The lens 114 may refract an incident light so as to focus the light toward the photosensitive element such as the photodiode 108 in the semiconductor substrate 104.

In an embodiment, the optical sensor device 102 is a backside illuminated image sensor. In an embodiment, the optical sensor device 102 is an infrared sensor, for example, for sensing a far infrared light. In an embodiment, a pixel of the optical sensor device 102 may be defined by a region unit of the semiconductor substrate 104 surrounded by the trench isolation element 106. In an embodiment, the pixels are defined by regions surrounded by the grid structure 112. Alternatively, the openings 1120 of the grid structure 112 may correspond to the pixels, and/or may correspond to the region units of the semiconductor substrate 104 surrounded by the trench isolation element 106. In an embodiment, the pixels of the optical sensor device 102 may respectively correspond to units of the lens 114, and/or the photosensitive elements such as the photodiodes 108, and so on.

In the optical sensor device 102 according to embodiments, the textured surface of the back semiconductor surface 1048 of the semiconductor substrate 104 may diffract a sensing light so as to increase a path length of the light. The photodiode 108 having a thick thickness may aid increasing the path length of the sensing light. The trench isolation element 106 is extended through all of the thickness of the semiconductor substrate 104, with which light interference between adjacent pixels can be avoided. Therefore, a light quantum effect as well as sensing efficiency and accuracy of the optical sensor device 102 can be increased.

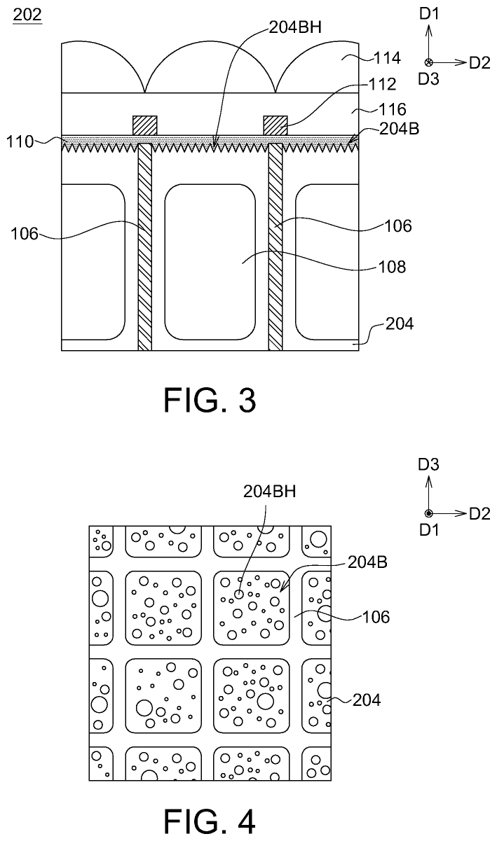

FIG. 3 illustrates a diagrammatic cross-section view of an optical sensor device 202 according to another embodiment, which is different from the optical sensor device 102 in FIG. 1 as the following. In embodiments, a back semiconductor surface 204B of a semiconductor substrate 204 has a textured surface of nanometer scale size. FIG. 4 illustrates a schematic diagram of the semiconductor substrate 204 as viewed with facing toward the back semiconductor surface 204B according to an embodiment. Referring to FIG. 3 and FIG. 4 both, in an embodiment, the textured surface of the back semiconductor surface 204B may be formed by performing an etching process, for example, with a femtosecond laser method or other suitable methods, to the back semiconductor surface 204B exposed by the trench isolation element 106 so as to form voids 204BH of nanometer scale in the back semiconductor surface 204B. A size of the void 204BH, for example a size in the first direction D1, and/or a size in the second direction D2, and/or a size in the third direction D3 of the void 204BH, may be equal to or smaller than 100 nm, for example, being 40 nm, 50 nm, and so on, but is not limited thereto. In this embodiment, the textured surface of the semiconductor surface 104B of the optical sensor device 102 has a texture of nanometer scale size, which can improve light quantum effect as well as photosensitive efficiency of the device, better than an efficacy resulted from the textured surface of a larger size.

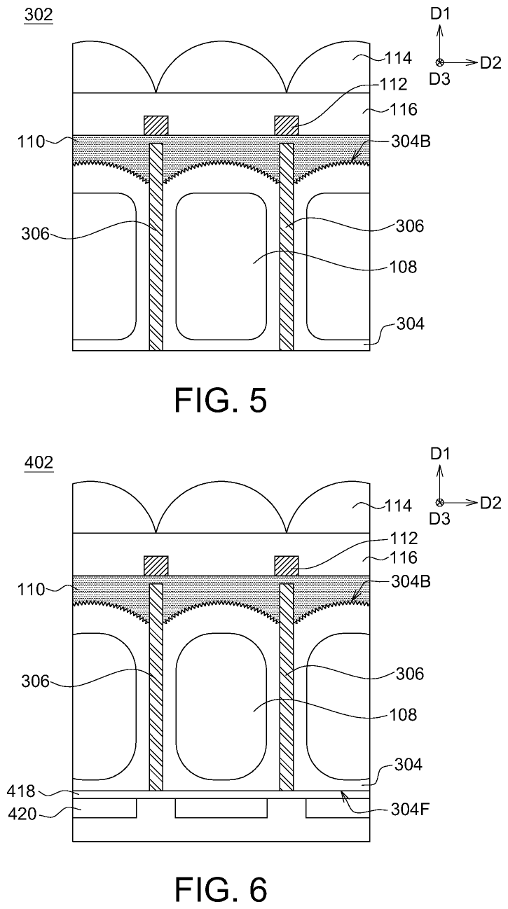

FIG. 5 illustrates a diagrammatic cross-section view of an optical sensor device 302 according to yet another embodiment, which is different from the optical sensor device 202 in FIG. 3 as the following. A back semiconductor surface 304B of a semiconductor substrate 304 has a lens shape surface. For example, the lens shape surface may be a convex-arc-like surface profile resulted from the semiconductor substrate 304 gradually thicken along a lateral direction (parallel to the second direction D2) away from the trench isolation element 106. The lens shape surface may be formed with using a laser-spike annealing (LSA) method. The lens shape surface may aid concentrate a light path, which can reduce crosstalk (X-talk). In addition, the lens shape surface may have the textured surface of nanometer scale size, which can improve light quantum effect of the device. A trench isolation element 306 is exposed by the back semiconductor surface 304B, and extended to embed into the anti-reflective layer 110. The trench isolation element 306 may be separated from the grid structure 112 by the anti-reflective layer 110.

FIG. 6 illustrates a diagrammatic cross-section view of an optical sensor device 402 according to yet another embodiment, which is different from the optical sensor device 302 in FIG. 5 as the following. The optical sensor device 402 may further comprise a transistor. The transistor may be disposed on a front semiconductor surface 304F of the semiconductor substrate 304. In an embodiment, the transistor may comprise a dielectric layer 418 formed on the front semiconductor surface 304F, and a gate structure 420 (such as a gate electrode layer) on the dielectric layer 418. The transistor may also comprise a source and a drain, which may be formed in the semiconductor substrate 304 by using an ion implanting method. One of the doped source and the doped drain may be electrically connected to the photosensitive element such as the photodiode 108. For example, the one of the source and the drain is electrically connected to one of a P type doped portion and a N type doped portion of the photodiode 108. The transistors may be arranged to correspond to the pixels, respectively. In other embodiments, a relationship concept of the transistor relative to the other elements may be applied for embodiments referring to FIG. 1 and FIG. 3.

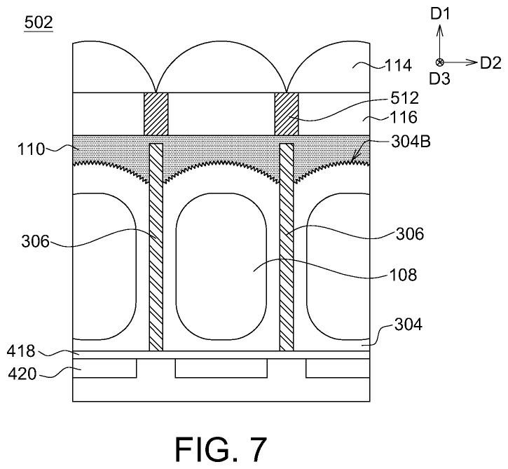

FIG. 7 illustrates a diagrammatic cross-section view of an optical sensor device 502 according to an embodiment, which is different from the optical sensor device 402 in FIG. 6 as the following. A grid structure 512 passes through the transparent layer 116, and is contact with the lens 114. A size of the grid structure 512 in the first direction D1 (e.g. thickness) may be equal to a size of the transparent layer 116 in the first direction D1 (e.g. thickness).

Accordingly, the optical sensor device according to concepts in embodiments may have at least one of the following advantages. The semiconductor substrate has the back semiconductor surface having the textured surface, and the textured surface may diffract a light by which a path length of a sensing light can be increased so as to improve quantum efficiency. The photodiode has a thick thickness, which can aid increasing the path length of the sensing light. The trench isolation element and/or the grid structure 112 may be used to reflect an incident light into the photosensitive element such as the photodiode, and with which photo sensing efficiency can be improved, light interference from an adjacent pixel can be avoided, and sensing accuracy can be increased. The lens may refract an incident light to focus the light to move toward the photosensitive element such as the photodiode in the semiconductor substrate. The back semiconductor surface of the semiconductor substrate may have the lens shape surface, and the lens shape surface can aid focusing a light path so as to reduce crosstalk. Therefore, the optical sensor device according to the concepts in embodiments can have excellent sensing efficiency and accuracy.

While the disclosure has been described by way of example and in terms of the exemplary embodiment(s), it is to be understood that the disclosure is not limited thereto. On the contrary, it is intended to cover various modifications and similar arrangements and procedures, and the scope of the appended claims therefore should be accorded the broadest interpretation so as to encompass all such modifications and similar arrangements and procedures.

1. An optical sensor device, comprising:
a semiconductor substrate having a back semiconductor surface and a front semiconductor surface opposing to the back semiconductor surface, wherein the back semiconductor surface has a lens shape surface, wherein the lens shape surface has a textured surface;
a trench isolation element extending from the back semiconductor surface to the front semiconductor surface; and
a photodiode in the semiconductor substrate.

2. The optical sensor device according to claim 1, wherein the textured surface is a surface having a topology with nanometer to micrometer-sized surface variation.

3. (canceled)

4. The optical sensor device according to claim 1, comprising pixel defined by a region of the semiconductor substrate surrounded by the trench isolation element.

5. The optical sensor device according to claim 1, further comprising a grid structure disposed on the back semiconductor surface.

6. The optical sensor device according to claim 5, comprising pixels, wherein the grid structure defines openings, the openings correspond to the pixels.

7. The optical sensor device according to claim 5, further comprising:
a transparent layer on the grid structure; and
a lens on the transparent layer.

8. The optical sensor device according to claim 7, wherein the grid structure passes through the transparent layer and is contact with the lens.

9. The optical sensor device according to claim 7, wherein the grid structure is separated from the lens by the transparent layer.

10. The optical sensor device according to claim 5, wherein the grid structure comprises a reflective material.

11. The optical sensor device according to claim 5, wherein the grid structure comprises a metal.

12. The optical sensor device according to claim 1, further comprising an anti-reflective layer on the back semiconductor surface.

13. The optical sensor device according to claim 12, wherein the trench isolation is embedded into the anti-reflective layer.

14. The optical sensor device according to claim 12, wherein the anti-reflective layer has a surface complementary to the textured surface of the back semiconductor surface of the semiconductor substrate.

15. The optical sensor device according to claim 1, wherein the optical sensor device is a backside illuminated image sensor.

16. The optical sensor device according to claim 1, wherein the optical sensor device is an infrared sensor.

17. The optical sensor device according to claim 1, further comprising a lens on the back semiconductor surface.

18. The optical sensor device according to claim 1, further comprising a transistor formed on the front semiconductor surface of the semiconductor substrate.
